(19) United States
(12) Patent Application Publication
(10) Pub. No.: US 2007/0177645 A1
(43) Pub. Date: Aug. 2, 2007

(54) Semiconductor laser device

(75) Inventor: Hiroyuki Hosoba, Higashihiroshima-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/698,187

(22) Filed: Jan. 26, 2007

(30) Foreign Application Priority Data
Jan. 30, 2006 (JP) 2006-021076

(51) Int. Cl. H01S 5/00

(52) U.S. Cl. 372/46.01

(57) ABSTRACT

A semiconductor laser device, comprising a buffer layer of a first conductivity type, a clad layer of the first conductivity type, an active layer and a clad layer of a second conductivity type formed on a semiconductor substrate of the first conductivity type, wherein a band gap in the buffer layer of the first conductivity type has a value which is greater than a band gap of the semiconductor substrate and smaller than a band gap of the clad layer of the first conductivity type, and an impurity concentration in the buffer layer of the first conductivity type is higher than an impurity concentration in the clad layer of the first conductivity type.

### CROSS-REFERENCE TO RELATED APPLICATION

This application is related to Japanese Patent Application No. 2006-021076 filed on Jan. 30, 2006 whose priority is claimed under 35 USC § 119 and the disclosure of which is incorporated by reference in its entirety.

### BACKGROUND OF THE INVENTION

1. Field of the Invention

The present invention relates to a III-V group compound semiconductor laser device, and in particular, to a GaAlAs based compound semiconductor laser device.

2. Description of the Related Art

Semiconductor laser devices are used as a light source for recording and reproduction in an optical disc which is a recording medium for audio and video, and in particular, GaAlAs based semiconductor laser devices are used to make recording possible with high density. In recent years, there has been a demand for increase in the optical output of GaAlAs based semiconductor laser devices, in order to increase the rate of recording. Therefore, it has been required for the operating voltage to be reduced, as well as for heat generation to be reduced, in order to gain excellent reliability.

In GaAlAs based semiconductor laser devices, however, a GaAs substrate and an AlGaAs clad layer having a high composite ratio of Al which is formed on the substrate so as to be adjacent to the substrate have the same conductivity and different band gaps, and therefore, potential is generated in the interface between these semiconductors (substrate and clad layer), due to the discontinuity of the band. The height of this potential barrier becomes great as the discontinuity of the band increases, and the discontinuity of the band between the two semiconductors becomes great as the difference in the band gap increases, and thus, the high potential barrier is generated. Therefore, when an AlGaAs based semiconductor laser device is formed, a problem arises, such that the operating voltage increases.

As a measure for solving this problem, a structure where a layer of which the band gap energy has a value between these two semiconductor materials, for example a buffer layer where the composition ratio of Al gradually changes between the GaAs layer and the GaAlAs clad layer is provided between the GaAs substrate and the AlGaAs clad layer having a high composition ratio of Al, has been proposed (for example, Japanese Unexamined Patent Publication H1 (1989)-175285). FIG. 6 is a cross sectional diagram showing such a semiconductor laser according to the prior art, and in the following, this GaAlAs based semiconductor laser device as the prior art is described in reference to FIG. 6.

The GaAlAs based semiconductor laser device as the prior art shown in FIG. 6 is made of an n type GaAs buffer layer 2 (Si doped; 1×10¹⁸ cm⁻³), an n type Ga₁₋ₓAlₓAs graded buffer layer 3 (Si doped; 1×10¹⁸ cm⁻³), an n type Ga₁₋ₓAlₓAs clad layer 4 (Si doped; 1×10¹⁸ cm⁻³), a Ga₁₋ₓAlₓAs active layer 5 (undoped), a p type Ga₁₋ₓAlₓAs clad layer 6 (Be doped; 5×10¹⁷ cm⁻³), a p type GaAs cap layer 7 (Be doped; 2×10¹⁸ cm⁻³) and a p type electrode 11, which are sequentially formed on an n type GaAs substrate 1 (Si doped; 2×10¹⁸ cm⁻³), as well as an n type electrode 10 formed on the rear surface of the substrate 1. In this case, in the n type Ga₁₋ₓAlₓAs graded buffer layer 3, the composition ratio x of Al gradually changes from 0 to the value of the composition ratio x of Al in the n type Ga₁₋ₓAlₓAs clad layer 4 from the n type GaAs buffer layer 2 to the n type Ga₁₋ₓAlₓAs clad layer 4.

In this prior art, an n type Ga₁₋ₓAlₓAs graded buffer layer 3 of which the composition ratio x of Al gradually changes between the n type Ga₁₋ₓAlₓAs clad layer 6 having a large band gap and the n type GaAs buffer layer 2 having a small band gap, that is to say, the band gap changes between the values of these two, is provided, and thereby, the discontinuity in the band can be reduced in the interface between the two layers.

In ridge-type semiconductor laser devices where an optical output of 300 mW or more is required in recent years, to which the structure of the above described GaAlAs based semiconductor laser device as the prior art applies, however, effects of reducing the operating voltage are not sufficient, due to the current path being narrow.

Furthermore, when the impurity concentration in the n type GaAs buffer layer 2 and the n type Ga₁₋ₓAlₓAs clad layer 4 is reduced so that the crystallinity of the active layer 5 on top of these improves, in order to increase the optical output of the GaAlAs based semiconductor laser device as the prior art, the effects of reducing the operating voltage further become further small in the case of a ridge type structure.

### SUMMARY OF THE INVENTION

In order to solve the above-mentioned problem of the prior art, an object of the present invention is to provide a semiconductor laser device having a high output, where reduction in the operating voltage can be achieved.

According to the present invention, provided is a semiconductor laser device comprising a buffer layer of a first conductivity type, a clad layer of the first conductivity type, an active layer and a clad layer of a second conductivity type formed on a semiconductor substrate of the first conductivity type, wherein a band gap in the buffer layer of the first conductivity type has a value which is greater than a band gap of the semiconductor substrate and smaller than a band gap of the clad layer of the first conductivity type, and an impurity concentration in the buffer layer of the first conductivity type is higher than an impurity concentration in the clad layer of the first conductivity type.

In a semiconductor laser device according to the present invention, the discontinuity of the band is reduced in comparison with conventional ridge type semiconductor layer devices where an optical output of 300 W or more is required, and therefore, the operating voltage of the laser device can be drastically reduced.

### BRIEF DESCRIPTION OF THE DRAWINGS

FIG. 1 is a cross sectional diagram showing a GaAlAs based compound semiconductor laser device according to the first embodiment of the present invention;

FIG. 2 is a graph showing the relationship between the impurity concentration of Si in the n type GaAlAs buffer layer and the operating voltage in each of the semiconductor lasers of Examples 1a to 1f of the present invention and Comparative Example 1;

FIG. 3 is a cross sectional diagram showing a GaAlAs based compound semiconductor laser device according to the second embodiment of the present invention;

FIG. 4 is a graph showing the relationship between the impurity concentration of Si in the n type GaAlAs buffer layer and the operating voltage in each of the semiconductor lasers of Examples 2a to 1e of the present invention and Comparative Example 2;

FIG. 5 is a cross sectional diagram showing a GaAlAs based compound semiconductor laser device according to the third embodiment of the present invention; and

FIG. 6 is a cross sectional diagram showing a semiconductor laser device according to the prior art.

### DESCRIPTION OF THE PREFERRED EMBODIMENTS

The present invention provides a semiconductor laser device comprising a buffer layer of a first conductivity type, a clad layer of the first conductivity type, an active layer and a clad layer of a second conductivity type formed on a semiconductor substrate of the first conductivity type, wherein a band gap in the buffer layer of the first conductivity type has a value which is greater than a band gap of the semiconductor substrate and smaller than a band gap of the clad layer of the first conductivity type, and an impurity concentration in the buffer layer of the first conductivity type is higher than an impurity concentration in the clad layer of the first conductivity type.

Semiconductor laser devices according to the present invention have a laminated structure where at least the semiconductor layers described above are formed on the semiconductor substrate and include those having a ridge structure, in addition to those where at least the clad layer of the first conductivity type or the clad layer of the second conductivity type is made up of plural layers, those where an etching stop layer is formed between the two layers in the case where the clad layer of the second conductivity type is made up of two layers, those where dielectric layers having insulating properties are formed on both sides of the ridge portion, those where an insulating film or a protective film are formed in the layers above the ridge portion and the like.

According to the present invention, first conductivity type means n type or p type, and second conductivity type means p type or n type, whichever is opposite to the first conductivity type.

The present invention can be applied to semiconductor laser devices, particularly those made of Ga₁₋ₓAlₓAs (0≦x≦1), and concretely, is appropriate for GaAlAs based semiconductor laser devices where the semiconductor substrate of the first conductivity type (band gap: about 1.42 eV) is made of GaAs and the buffer layer of the first conductivity type (band gap: about 1.5 eV to 1.7 eV), the clad layer of the first conductivity type (band gap: about 1.8 eV to 2.1 eV), the active layer and the clad layer of the second conductivity type are made of Ga₁₋ₓAlₓAs (0<x<1).

Furthermore, though the conductivity type of the substrate and each semiconductor layer may be either n type or p type, it is preferable for the first conductivity type to be n type and the second conductivity type to be p type, in that the discontinuity of the band in the n type interface is reduced, so that the operating voltage of the laser device can be reduced. Here, Si, Se and the like can be cited as impurity elements which make the conductivity type of GaAs n type and Zn, C, Mg and the like can be cited as impurity elements which make the conductivity type p type, and the conductivity type of the semiconductor substrate and each semiconductor layer can be determined using these impurity elements according to the present invention.

### (Description of Buffer layer of First Conductivity Type)

It is preferable for GaAlAs based semiconductor laser devices according to the present invention to be formed in such a manner that the composition ratio of Al in the buffer layer of the first conductivity type increases gradually (in stages or continuously) from the semiconductor substrate of the first conductivity type to the clad layer of the first conductivity type. In this manner, the operating voltage can further be reduced.

In addition, according to the present invention, it is preferable for the impurity concentration of the impurity element which is comprised in of the buffer layer of the first conductivity type and determines the conductivity type to be 5×10¹⁷ cm⁻³ or more, and it is more preferable for it to be from 5×10¹⁷ cm⁻³ to 2×10¹⁸ cm⁻³. In this manner, the discontinuity of the band in the interface between the substrate and the clad layer can be effectively reduced. In particular, it is preferable for the impurity concentration in the Ga₁₋ₓAlₓAs buffer layer of the first conductivity type to be higher than 5×10¹⁷ cm⁻³, and thereby, defects and dislocation in the clad layer can be effectively prevented from being transferred to the active layer. Here, in the case where the impurity concentration of the buffer layer of the first conductivity type is lower than 5×10¹⁷ cm⁻³, the operating voltage becomes as great as 2.5 V or higher, and a problem arises, such that the reliability is lowered due to heat generation.

According to the present invention, the buffer layer of the first conductivity type may be formed of the plural layers. In this case, it is preferable for the composition ratio of Al in the GaAlAs buffer layer of the first conductivity type to increase in stages as described above from the GaAs semiconductor substrate of the first conductivity type to the GaAlAs clad layer side of the first conductivity type, in order to further reduce the discontinuity of the band and further reduce the operating voltage of the laser device.

In addition, in the case where the buffer layer of the first conductivity type is made up of the plural layers in this manner, it is preferable for the impurity concentration of the buffer layer to increase in stages from the substrate side to the clad layer side.

In addition, a GaAs buffer layer of the first conductivity type which does not include Al may be provided between the GaAs semiconductor substrate of the first conductivity type and the Ga₁₋ₓAlₓAs buffer layer of the first conductivity type. In this manner, defects and dislocation in the semiconductor substrate can be prevented from being transferred to the active layer, and the operating voltage can be reduced while preserving excellent crystallinity. At this time, it is preferable for the impurity concentration of the impurity element which is comprised in the GaAs buffer layer of the first conductivity type and determines the conductivity type to be 1×10¹⁸ cm⁻³ or less, and it is more preferable for it to be 5×10¹⁷ cm⁻³ to 1×10¹⁸ cm⁻³. Here, in the case where the impurity concentration in the GaAs buffer layer of the first conductivity type is higher than 1×10¹⁸ cm⁻³, defects and dislocations in the semiconductor substrate are easily transferred to the active layer, though the operating voltage is not affected.

Furthermore, it is preferable for the thickness of the region of the buffer layer of the first conductivity type in the vicinity of the interface between the buffer layer and the clad layer of the first conductivity type, of which the impurity concentration is higher than that of the clad layer, to be 70 nm or less, and it is more preferable for it to be 70 nm to 30 nm. In this manner, defects and dislocation in the clad layer can be effectively prevented from being transferred to the active layer. Here, in the case where the thickness of the above described region in the vicinity of the interface is greater than 70 nm, the effects of reducing the operating voltage are lessened, making the operating voltage becomes as great as 2.5 V or higher, and a problem arises, such that the reliability is lowered due to heat generation.

### (Description of Clad Layer of First Conductivity Type)

According to the present invention, it is preferable for the impurity concentration of the impurity element which is comprised in the clad layer of the first conductivity type and determines the conductivity type to be 1×10¹⁷ cm⁻³ to 1×10¹⁸ cm⁻³. In this manner, defects and dislocation in the clad layer can be effectively prevented from being transferred to the active layer. At this time, the impurity concentration in the clad layer of the first conductivity type is set low in comparison with the impurity concentration in the vicinity of the interface between the buffer layer of the first conductivity type and the clad layer of the first conductivity type, as described above. Here, in the case where the impurity concentration in the clad layer of the first conductivity type is higher than 1×10¹⁸ cm⁻³, there are many defects in the crystal, which work as centers of non-emission of light, thus making the operating current great.

Next, the present invention is described in further detail in reference to the drawings showing embodiments. Here, the present invention is not limited to the embodiments shown in the drawings.

### First Embodiment

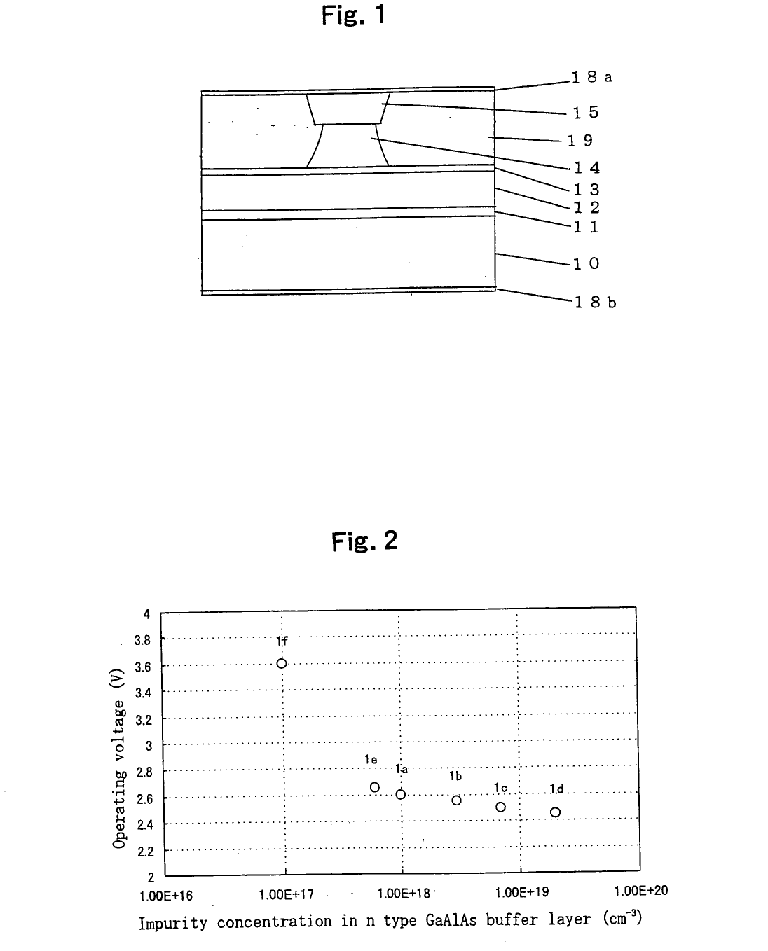

FIG. 1 is a cross sectional diagram showing a GaAlAs based compound semiconductor laser device according to the first embodiment of the present invention.

This GaAlAs based compound semiconductor laser device (hereinafter sometimes simply referred to as semiconductor laser device) has a structure where an n type Ga_{0.9}Al_{0.1}As buffer layer 11, an n type Ga_{0.5}Al_{0.5}As clad layer 12, a Ga_{0.9}Al_{0.1}As active layer 13, a p type Ga_{0.5}Al_{0.5}As clad layer 14, a p type GaAs contact layer 15 and a p type electrode 18a are formed in this order on top of an n type GaAs substrate 10 (Si doped; 1×10¹⁸ cm⁻³), an n type electrode 18b is formed on a rear surface of the substrate 10, a ridge portion (width of ridge: 3 μm) is formed of the p type Ga_{0.5}Al_{0.5}As clad layer 14 and the p type GaAs contact layer 15, and a GaAs current blocking layer 19 is formed on both sides of the ridge portion.

### EXAMPLE 1

A semiconductor laser device having the ridge structure according to the above described first embodiment was fabricated in the following manner.

First, a Ga_{0.9}Al_{0.1}As layer was grown on top of an n type GaAs substrate 10 having a thickness of 350 μm in accordance with an MOCVD method. Here, an n type Ga_{0.9}Al_{0.1}As buffer layer 11 where the composition ratio x of Al was 0.1, the concentration of the n conductivity type impurity was 1×10¹⁸ cm⁻³, and the film thickness was 70 nm was formed by adjusting the ratio of the flow amount (volume ratio) in the raw material gas to AsH₃ gas:TMG gas:TMA gas:SiH₄ gas=50:5:1:10.

Next, the ratio of the flow amount (volume ratio) was adjusted to AsH₃ gas:TMG gas:TMA gas:SiH₄ gas=10:1:1:1, and thereby, an n type Ga_{0.5}Al_{0.5}As clad layer 12 where the composition ratio x of Al was 0.5, the film thickness was 1 μm and the concentration of Si was 5×10¹⁷ cm⁻³ was formed in accordance with an MOCVD method.

Next, the ratio of the flow amount (volume ratio) was adjusted to AsH₃ gas:TMG gas:TMA gas=50:5:1, and thereby, a Ga_{0.9}Al_{0.1}As active layer 13 where the composition ratio x of Al was 0.1 and the film thickness was 500 nm was formed in accordance with an MOCVD method.

Subsequently, the ratio of the flow amount (volume ratio) was adjusted to AsH₃ gas:TMG gas:TMA gas:DEZn gas=10:1:1:0.5, and thereby, a p type Ga_{0.5}Al_{0.5}As clad layer 14 where the composition ratio x of Al was 0.5, the concentration of the p conductivity type impurity was 1×10¹⁸ cm⁻³ and the film thickness was 1 μm was formed in accordance with an MOCVD method.

Next, the ratio of the flow amount (volume ratio) was adjusted to AsH₃ gas:TMG gas:DEZn gas=10:1:0.5, and thereby, a p type GaAs contact layer 15 where the concentration of Zn was 5×10¹⁸ cm⁻³ and the film thickness was 1 μm was formed in accordance with an MOCVD method.

After that, a mask in band form with a width of 3 μm was formed on top of the p type GaAs contact layer 15 for the formation of a ridge (current path), the p type GaAs contact layer 15 and the p type Ga_{0.5}Al_{0.5}As clad layer 14 were etched up to the vicinity of the GaAs active layer 13 in accordance with a wet etching technique, so that a ridge form (ridge width) for gaining desired laser properties was formed, a GaAs current blocking layer 19 was formed, in order to prevent a current from flowing to the surface on both sides of the ridge, a p type electrode 18a made of AuZn/Au having a film thickness of 300 nm was formed on top of the p type GaAs contact layer 15 and the GaAs current blocking layer 19, an n type electrode 18b made of AuSn/Au having a film thickness of 300 nm was formed on the rear surface of the n type GaAs substrate 10, and this was cut into chip units, so that a semiconductor laser device (prototype 1a) was gained.

Semiconductor laser devices of prototypes 1b, 1c, 1d and 1e, which are Examples 1, and 1f, which is Comparative Example 1, were fabricated in the same manner as with the prototype 1a, except that the impurity concentration of Si in the n type Ga_{0.9}Al_{0.1}As buffer layer 11 changed to 1×10¹⁷ cm⁻³, 6×10¹⁷ cm⁻³, 3×10¹⁸ cm⁻³, 7×10¹⁸ cm⁻³ and 2×10¹⁹ cm⁻³.

The operating voltage when each semiconductor laser device of the fabricated prototypes 1a to 1e (Examples 1) and prototype 1f (Comparative Example 1) were operated with an optical output of 100 mW was measured, and the relationship between the impurity concentration of Si in the n type GaAlAs buffer layer 11 and the operating voltage in each semiconductor laser is shown in FIG. 2. Here, the lateral axis in FIG. 2 indicates the impurity concentration of Si in logarithm, and the impurity concentration of Si in the prototypes 1a to 1f were 1a: 1×10¹⁸ cm⁻³, 1b: 3×10¹⁸ cm⁻³, 1c: 7×10¹⁸ cm⁻³, 1d: 2×10¹⁹ cm⁻³, 1e: 6×10¹⁷ cm⁻³ and 1f: 1×10¹⁷ cm⁻³.

It was found from the results in FIG. 2 that the operating voltage at room temperature when the output was 100 mW was 3.5 V or more in the prototype 1f (Comparative Example 1), where the impurity concentration of the n type GaAlAs buffer layer 11 was 1×10¹⁷ cm⁻³, which is lower than that of the n type GaAlAs clad layer 12, while the operating voltage suddenly dropped when the impurity concentration of the n type GaAlAs buffer layer 11 was made greater than the impurity concentration of the n type GaAlAs clad layer 12, as in the prototypes 1a to 1e (Examples 1), and the operating voltage significantly dropped, and a low operating voltage of approximately 2.7 V or less could be stably gained when the impurity concentration was 6×10¹⁷ cm⁻³ or more, as in the prototype 1e.

That is to say, it can be seen in Examples 1 that, as described above, the composition ratio x of Al in the n type Ga₁₋ₓAlₓAs buffer layer 11 was set to 0.1 so as to be the band gap value between the n type GaAs substrate 10 and the n type Ga_{0.5}Al_{0.5}As clad layer 12, and in addition, the impurity concentration of Si was made greater than the impurity concentration of Si in the n type Ga_{0.5}Al_{0.5}As clad layer 12, and thereby, the potential barrier resulting from the discontinuity of the band between the n type GaAs substrate 10 and the n type Ga_{0.5}Al_{0.5}As clad layer 12 was lowered in comparison with Comparative Example 1, and therefore, the operating voltage was drastically reduced.

Here, though in Examples 1, the composition ratio x of Al in the n type Ga₁₋ₓAlₓAs buffer layer 12 was 0.1, it was confirmed that the operating voltage was lowered a great deal when the impurity concentration of Si in the n type Ga₁₋ₓAlₓAs buffer layer 11 was made higher than the impurity concentration of Si in the n type Ga_{0.5}Al_{0.5}As clad layer 12.

### Second Embodiment

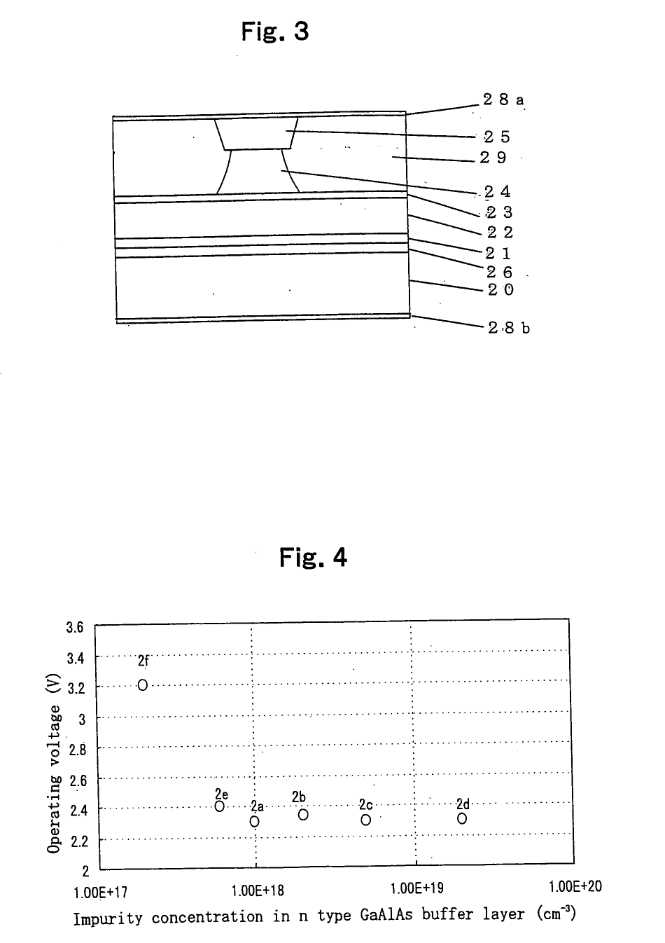

FIG. 3 is a cross sectional diagram showing a GaAlAs based compound semiconductor laser device according to the second embodiment of the present invention.

This semiconductor laser device has a structure where an n type GaAs buffer layer 26, an n type Ga_{0.75}Al_{0.25}As buffer layer 21, an n type Ga_{0.5}Al_{0.5}As clad layer 22 (Si doped; 5×10¹⁷ cm⁻³), a Ga_{0.9}Al_{0.1}As multiple quantum well active layer 23 (undoped), a p type Ga_{0.5}Al_{0.5}As clad layer 24 (Zn doped; 1×10¹⁸ cm⁻³), a p type GaAs contact layer 25 (Zn doped; 5×10¹⁸ cm⁻³) and a p type electrode 28 are formed in this order on top of an n type GaAs substrate 20 (Si doped; 1×10¹⁸ cm⁻³), an n type electrode 28b is formed on the rear surface of the substrate 20, a ridge portion (ridge width: 3 μm) is formed of the p type Ga_{0.5}Al_{0.5}As clad layer 24 and the p type GaAs contact layer 25, and a GaAs current blocking layer 29 is formed on both sides of the ridge portion.

### EXAMPLE 2

A semiconductor laser device having a ridge structure according to the above described second embodiment was fabricated in the following manner.

First, an n type GaAs buffer layer 26 having an impurity concentration of 5×10¹⁷ cm⁻³ and a film thickness of 50 nm was formed on top of an n type GaAs substrate 20 having a thickness of 350 μm in accordance with an MOCVD method.

Next, the ratio of the flow amount (volume ratio) was adjusted to AsH₃ gas:TMG gas:TMA gas:SiH₄ gas=10:1:1:2, and thereby, an n type Ga_{0.75}Al_{0.25}As buffer layer 21 where the composition ratio x of Al was 0.25, the concentration of the n conductivity type impurity was 1×10¹⁸ cm⁻³ and the film thickness was 50 nm was formed on top of the n type GaAs buffer layer 26.

After that, approximately the same method as in the above described Example 1 was used, except that the impurity concentration and the composition ratio of Al were set as described above in reference to FIG. 3, so that an n type Ga_{0.5}Al_{0.5}As clad layer 22 (film thickness: 1 μm), a Ga_{0.9}Al_{0.1}As multiple quantum well active layer 23 (total film thickness: 100 nm), a p type Ga_{0.5}Al_{0.5}As clad layer 24 (film thickness: 1 μm), a p type GaAs contact layer 25 (film thickness: 1 μm), a GaAs current blocking layer 29, a p type electrode 28a and an n type electrode 28b were formed, and thus, a semiconductor laser device of a prototype 2a was gained.

Prototypes 2b, 2c, 2d and 2e, which are Examples 2, and 2f, which is Comparative Example 2, were fabricated in the same manner as the prototype 2a, except that the impurity concentration of Si in the n type Ga_{0.75}Al_{0.25}As buffer layer 21 changed to 2×10₁₇ cm⁻³, 6×10¹⁷ cm⁻³, 2×10¹⁸ cm⁻³, 5×10¹⁸ cm⁻³ and 2×10¹⁹ cm⁻³.

The operating voltage when each semiconductor laser device of the fabricated prototypes 2a to 2e (Examples 2) and prototype 2f (Comparative Example 2) were operated with an optical output of 100 mW was measured, and the relationship between the impurity concentration of Si and the operating voltage in the n type GaAlAs buffer layer 21 in each semiconductor laser is shown in FIG. 4. Here, the lateral axis in FIG. 4 indicates the impurity concentration of Si in logarithm, and the impurity concentration of Si in the prototypes 2a to 2f were 2a: 1×10¹⁸ cm⁻³, 2b: 2×10¹⁸ cm⁻³, 2c: 5×10¹⁸ cm⁻³, 2d: 2×10¹⁹ cm⁻³, 2e: 6×10¹⁷ cm⁻³ and 2f: 2×10¹⁷ cm⁻³.

It was found from the results in FIG. 4 that the operating voltage at room temperature when the output was 100 mW was 3.2 V or more in the prototype 2f (Comparative Example 2), where the impurity concentration in the n type GaAlAs buffer layer 21 was lower than the impurity concentration in the n type GaAlAs clad layer 22; 5×10¹⁷ cm⁻³, while the operating voltage dropped when the impurity concentration in the n type GaAlAs buffer layer 21 was made greater than the impurity concentration in the n type GaAlAs clad layer 22, as in the prototypes 2a to 2e (Examples 2), and the operating voltage significantly dropped, and a low operating voltage of approximately 2.4 V or less could be stably gained when the impurity concentration was 6×10¹⁷ cm⁻³ or more, as in the prototype 2e.

In Examples 2, an n type GaAs buffer layer 26 was provided between the n type GaAlAs buffer layer 21 and the n type GaAs substrate 20 as described above, and the impurity concentration (1×10¹⁸ cm⁻³) in the n type GaAlAs buffer layer 21, which was located between the n type GaAs buffer layer 26 and the n type GaAlAs clad layer 22, was set greater than the impurity concentration (5×10¹⁷ cm⁻³) in these. It may be considered, as a result of this, that approximately the same effects of the potential barrier lowering as a result of the modification of the discontinuation of the band as gained in Examples 1 could be gained in Examples 2. In addition, the impurity concentration in the n type GaAs buffer layer 26, the n type GaAlAs clad layer 22 and the n type GaAlAs buffer layer 21 were reduced as a whole, and therefore, it can be considered that the crystallinity of the GaAlAs multiple quantum well active layer 23 was improved, and the luminous efficiency was increased, making the operating current value lower, and as a result, the operating voltage was further reduced in comparison with Examples 1.

### Third Embodiment

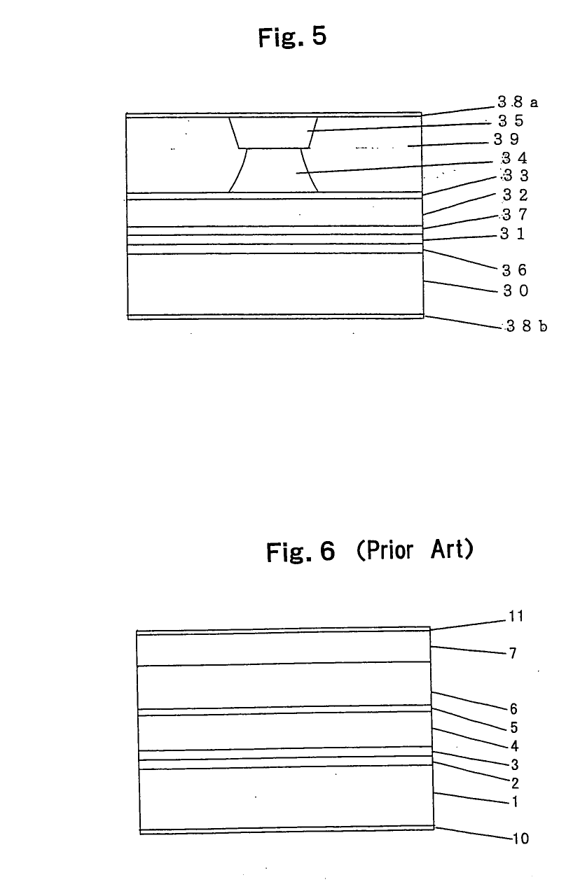

FIG. 5 is a cross sectional diagram showing a GaAlAs based compound semiconductor laser device according to the third embodiment of the present invention.

This semiconductor laser device has a structure where an n type GaAs buffer layer 36 (Si doped; 5×10¹⁷ cm⁻³), an n type Ga_{0.8}Al_{0.2}As first buffer layer 31 (Si doped; 5×10¹⁷ cm⁻³), an n type Ga_{0.65}Al_{0.35}As second buffer layer 37 (Si doped; 1×10¹⁸ cm⁻³), an n type Ga_{0.5}Al_{0.5}As clad layer 32 (Si doped; 5×10¹⁷ cm⁻³), a Ga_{0.9}Al_{0.1}As active layer 33 (undoped), a p type Ga_{0.5}Al_{0.5}As clad layer 34 (Zn doped; 1×10¹⁸ cm⁻³), a p type GaAs contact layer 35 (Zn doped; 5×10¹⁸ cm⁻³) and a p type electrode 38a are formed in this order on top of an n type GaAs substrate 30 (Si doped; 1×10¹⁸ cm⁻³), an n type electrode 38b is formed on the rear surface of the substrate 30, a ridge portion (ridge width: 3 μm) is formed of the p type Ga_{0.5}Al_{0.5}As clad layer 34 and the p type GaAs contact layer 35, and a GaAs current blocking layer 39 is formed on both sides of the ridge portion.

### EXAMPLE 3

A semiconductor laser element having a ridge structure according to the above described third embodiment was fabricated in accordance with an MOCVD method, in the same manner as in the above described Example 2, by setting the impurity concentration and the composition ratio of Al as described in reference to FIG. 5. At this time, the thickness of the layers are as follows. The n type GaAs substrate 30 was 100 μm, the n type GaAs buffer layer 36 was 500 nm, the n type Ga_{0.8}Al_{0.2}As first buffer layer 31 was 70 nm, the n type Ga_{0.65}Al_{0.35}As second buffer layer 37 was 70 nm, the n type Ga_{0.5}Al_{0.5}As clad layer 32 was 1 μm, the Ga_{0.9}Al_{0.1}As active layer 33 was 700 nm, the p type Ga_{0.5}Al_{0.5}As clad layer was 1 μm, the p type GaAs contact layer 35 was 1 μm, the p type electrode 38a was 300 nm and the n type electrode 38b was 300 nm.

The operating voltage when the fabricated semiconductor laser element of Example 3 was operated with an optical output of 100 mW was measured and found to be 2.3 V.

The structure of the semiconductor laser device of Example 3 is different from the structure of Example 1 in that the buffer layer is made up of three layers and the buffer layer which makes contact with the n type GaAs substrate is an n type GaAs buffer layer, and furthermore, the other two buffer layers are first and second n type GaAlAs buffer layers having a different impurity concentration, composition ratio of Al and film thickness. Therefore, the difference in the band gap between the n type GaAs substrate and the n type GaAlAs clad layer can be made smaller gradually (or in stages) in the number of n type buffer layers in Example 3, as compared to Example 1, and thereby, it can be considered that the effects the potential barrier lowering as a result of the modification of the discontinuity of the band are increased, and the operating voltage is further reduced. At this time, the film thickness of the n type GaAlAs second buffer layer that makes contact with the n type GaAlAs clad layer is as small as 70 nm in Example 3, and therefore, defects and dislocation are not transferred to the active layer, even when caused in the buffer layer, and thus, there is an advantage that excellent crystallinity can be maintained.

Here, though in Example 3, the film thickness of the n type GaAlAs second buffer layer is 70 nm, it was confirmed that a low operating voltage of approximately 2.3 V can be gained even when the film thickness is made smaller, that is, 30 nm.

### Other Embodiments

1. Though in the above described Embodiments 1 to 3, cases where the p type GaAlAs clad layer is made up of one layer are illustrated, the p type GaAlAs clad layer may be formed of two layers, so that a GaAs etching stop layer is formed between these two layers.

2. Though in the above described Embodiments 1 to 3, cases of a semiconductor laser device having a ridge structure are illustrated, it is possible to apply the present invention to semiconductor laser devices having a structure other than a ridge structure (for example oxide stripe type).

3. Though in the above described Embodiments 1 to 3, cases where Si is used as an impurity element of the n conductivity type are illustrated, Se can be used instead of Si, and Mg or C can be used as an impurity element of the p conductivity type instead of Zn.

4. Though in the above described examples, cases where films are formed as the respective semiconductor layers which form a semiconductor laser device in accordance with an MOCVD method are illustrated, the manufacturing method is not limited to this, and an MBE method, for example, may be used.

The present invention can be applied to semiconductor laser devices with a high output which can be used for read-out, write-in and erasing in CD-R/RW's, DVD-R/RW's or the like, and in particular, is appropriate for GaAlAs based semiconductor laser devices.

What is claimed is:

1. A semiconductor laser device, comprising a buffer layer of a first conductivity type, a clad layer of the first conductivity type, an active layer and a clad layer of a second conductivity type formed on a semiconductor substrate of the first conductivity type,
wherein a band gap in the buffer layer of the first conductivity type has a value which is greater than a band gap of the semiconductor substrate and smaller than a band gap of the clad layer of the first conductivity type, and
an impurity concentration in the buffer layer of the first conductivity type is higher than an impurity concentration in the clad layer of the first conductivity type.

2. The semiconductor laser device according to claim 1, wherein the semiconductor substrate of the first conductivity type is made of GaAs and the buffer layer of the first conductivity type, the clad layer of the first conductivity type and the clad layer of the second conductivity type are made of Ga₁₋ₓAlₓAs (0<x<1).

3. The semiconductor laser device according to claim 1, wherein the first conductivity type is n type and the second conductivity type is p type.

4. The semiconductor laser device according to claim 2, wherein the composition ratio of Al in the buffer layer of the first conductivity type gradually increases from the semiconductor substrate of the first conductivity type to the clad layer of the first conductivity type.

5. The semiconductor laser device according to claim 1, wherein the buffer layer of the first conductivity type is made up of plural layers.

6. The semiconductor laser device according to claim 2, further comprising a GaAs buffer layer of the first conductivity type between the GaAs semiconductor substrate of the first conductivity type and the Ga₁₋ₓAlₓAs buffer layer of the first conductivity type.

7. The semiconductor laser device according to claim 1, wherein the impurity concentration of the buffer layer of the first conductivity type is 5×10¹⁷ cm⁻³ or more.

8. The semiconductor laser device according to claim 1, wherein the impurity concentration of the clad layer of the first conductivity type is 1×10¹⁸ cm⁻³ or less.

9. The semiconductor laser device according to claim 6, wherein the impurity concentration of the GaAs buffer layer of the first conductivity type is 1×10¹⁸ cm⁻³ or less.

10. The semiconductor laser device according to claim 2, wherein the impurity concentration in the AlₓGa₁₋ₓAs buffer layer of the first conductivity type is higher than 5×10¹⁷ cm⁻³ in the vicinity of the interface where the AlₓGa₁₋ₓAs buffer layer of the first conductivity type makes contact with the AlₓGa₁₋ₓAs clad layer of the first conductivity type.

11. The semiconductor laser device according to claim 1, wherein a thickness of the region in the buffer layer of the first conductivity type, which is in the vicinity of the interface between the buffer layer of the first conductivity type and the clad layer of the first conductivity type, and where the impurity concentration is higher than that in the clad layer of the first conductivity type, is 70 nm or less.
